(19) United States
(12) Patent Application Publication
(10) Pub. No.: US 2007/0076380 A1
(43) Pub. Date: Apr. 5, 2007

(54) Structure for fixing adaptor to server

(75) Inventors: Lin-Wei Chang, Taipei (TW); Chi-Kang Hsieh, Taipei (TW)

Correspondence Address: EDWARDS & ANGELL, LLP, P.O. BOX 55874, BOSTON, MA, 02205, US

(73) Assignee: Inventec Corporation, Taipei (TW)

(21) Appl. No.: 11/365,577

(22) Filed: Feb. 28, 2006

(30) Foreign Application Priority Data
Aug. 25, 2005 (TW) 094214595

(51) Int. Cl. H05K 5/00

(52) U.S. Cl. 361/732

(57) ABSTRACT

A structure for fixing an adaptor to a server having a space is provided. The fixing structure includes at least one first coupling portion provided on at least one side of the space; at least one second coupling portion provided on at least one side of the adaptor and corresponding to the at least one first coupling portion; and at least one coupling component provided on the at least one second coupling portion, for securely coupling the first coupling portion to the second coupling portion. This arrangement allows power supplies to be easily assembled or disassembled to or from the server by the adaptor through the use of the fixing structure.

### FIELD OF THE INVENTION

The present invention relates to structures for fixing adaptors, and more particularly, a structure for fixing an adaptor to a space of a server.

### BACKGROUND OF THE INVENTION

Computers are playing a more and more important role at present. A high-performance computer should not only have a central processing unit (CPU) with high speed and a random access memory (RAM) with enough capacity but also have a power supply for providing stable power.

To ensure long working time of computers, especially of industrial computers or servers, a plurality of spare power supplies must be provided in order to supply power stably. For example, when a plurality of power supplies are provided in a server, an adaptor having drop-out lines must be added therein for electrically connecting inputs of the adaptor to the power supplies, electrically connecting an output of the adaptor to a motherboard in the server, and automatically switching to properly functioning power supplies to provide stable power.

The power supplies used in the server are mounted in the server from an opening in a back slot of the casing, and the adaptor electrically connected to each power supply is also mounted in the server. Generally, if the size of the motherboard is small (for example, a 1 U or 2 U motherboard), the power supply system including the power supplies and the adaptor can be disposed on the same plane as the motherboard, i.e. the assembling or disassembling of the power supply system and the motherboard may not affect to each other; however if the motherboard is too large (for example, a 3 U or 4 U motherboard) that the power supply system and the motherboard cannot be disposed on the same plane, then the server is separated into an upper layer and a lower layer, wherein the lower layer has a slot for inserting the power supplies from outside and the adaptor is mounted at a location inside the server which corresponds to the slot; whereas the motherboard is fastened to the upper layer.

The power supply must be electrically connected to the adaptor prior to mounting a motherboard of a 3 U or 4 U server, since the size of the motherboard is large. This means if the adaptor of the power supply system needs to be changed or repaired, the motherboard must be demounted first, this may cause inconvenience in the process. Furthermore, the motherboard may be prone to damage as a result of frequent mounting and demounting. In addition, it is more complicated in mounting or demounting as a plurality of screws must be fastened or unfastened.

As a result, the problem to be solved here is to provide a structure for conveniently assembling or disassembling the adaptor to or from the server without moving the large-size motherboard.

### SUMMARY OF THE INVENTION

In light of the above-mentioned problems, an objective of the present invention is to provide a structure for fixing an adaptor for connecting power supplies to a server, so as to allow the power supplies to be conveniently assembled or disassembled to or from the adaptor.

Another objective of the present invention is to provide a structure for fixing an adaptor for connecting power supplies to a server, without having to demount a motherboard of the server before assembling or disassembling the power supplies to or from the adaptor.

To achieve the above-mentioned and other objectives, the present invention proposes a structure for fixing an adaptor to a server having a space. The structure may be referred to as the “fixing structure” hereinafter. The fixing structure comprises: at least one first coupling portion provided on at least one side of the space; at least one second coupling portion provided on at least one side of the adaptor and corresponding to the at least one first coupling portion; and at least one coupling component provided on the at least one second coupling portion, for securely coupling the first coupling portion to the second coupling portion.

Preferably, the first coupling portion includes a protruded portion disposed on the side of the space. The first coupling portion further includes a coupling hole formed in the protruded portion, wherein the coupling hole can be a threaded hole. The second coupling portion comprises a projecting piece extending from the side of the adaptor, wherein the projecting piece is selectively disposed on one end of the side of the adaptor. The second coupling portion further includes a mounting hole for being coupled to the coupling component. The coupling component can be a screw such as a headed screw.

Compared to the prior art, there is no need to screw or unscrew a plurality of screws during a mounting or demounting process of the adaptor to or from the server through the use of the fixing structure of the present invention, thereby saving time and labor required for screwing or unscrewing the plurality of screws in the prior art. Therefore, the present invention can also the complexity problem in mounting or demounting of the adaptor in the prior art and also makes assembly or disassembly of power supplies convenient to implement.

Moreover, in the prior art, the power supplies must be electrically connected to the adaptor before the motherboard is mounted to the server, however in the present invention, the adaptor with the power supplies can be mounted or demounted to or from the server easily and time-effectively without moving the motherboard, such that a large-size motherboard can be used in the present invention. Thus, the inconvenience of demounting the motherboard before changing or repairing the adaptor with the power supplies in the prior art can be overcome and the risk of damaging the motherboard due to frequently mounting or demounting thereof can be effectively prevented according to the present invention.

### BRIEF DESCRIPTION OF THE DRAWINGS

The present invention can be more fully understood by reading the following detailed description of the preferred embodiments, with reference made to the accompanying drawings, wherein:

FIG. 1 is an exploded view of a structure for fixing an adaptor of a server according to a preferred embodiment of the present invention;

FIG. 2 is a schematic diagram showing another side of the adaptor in FIG. 1; and

FIGS. 3 to 6 are schematic diagram showing an adaptor being mounted to a server having a space by the fixing structure according to the preferred embodiment of the present invention, wherein FIG. 3 shows the server mounted with a motherboard, FIG. 4 shows the motherboard provided with a plurality of system components, FIG. 5 shows that the adaptor is to be mounted on the server by the fixing structure, and FIG. 6 shows that the adaptor has been mounted on the server by the fixing structure.

### DETAILED DESCRIPTION OF THE PREFERRED EMBODIMENTS

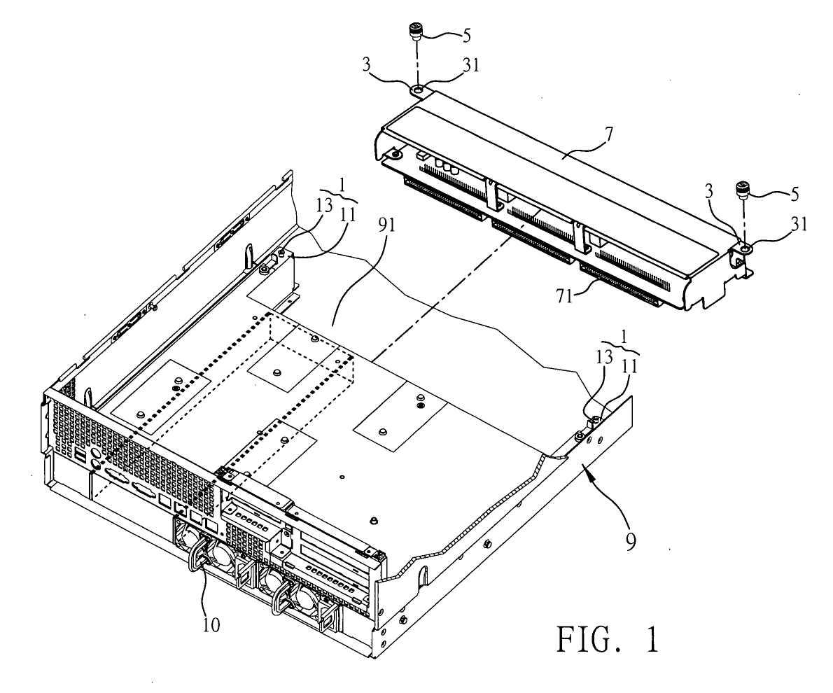

Preferred embodiments of a structure for fixing ad adaptor to a server as proposed in the present invention are described as follows with reference to FIGS. 1-6. It should be noted that the drawings are simplified schematic diagrams only showing components related to the present invention, and the arrangement of components could be more complex in practical implementation.

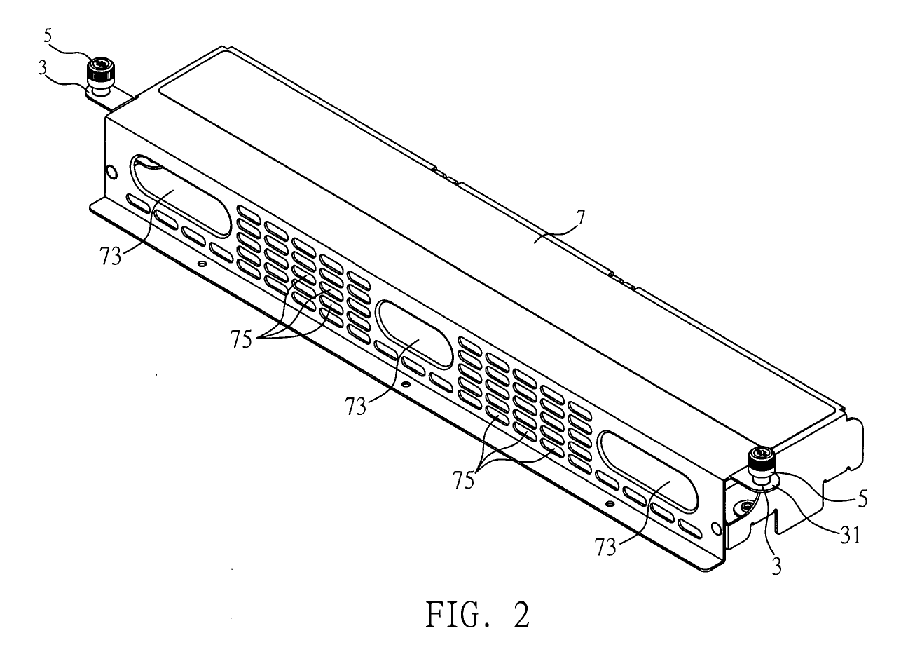

Referring to FIG. 1, it is an exploded view of the structure for fixing an adaptor to a server according to a preferred embodiment of the present invention. The structure may be referred to as the “fixing structure” in the description of the present invention. As shown in FIG. 1, the fixing structure of this embodiment comprises first coupling portions 1, second coupling portions 3 and coupling components 5. In this embodiment, the fixing structure can be used to assemble an adaptor 7 for connecting power supplies to a server 9 having a space 91. As shown in FIGS. 1 and 2, the adaptor 7 includes a plurality of electrical connection portions 71 for being electrically connected to power supplies 10, a plurality of openings 73 for drop out lines (not shown), and a plurality of ventilation holes 75 for heat dissipation. It should be noted that besides the server and adaptor having the above-described structures, other conventional servers and adaptors are also suitably applied in the present invention.

The first coupling portions 1 are disposed on two opposite sides of the space 91 of the server 9. In this embodiment, each of the first coupling portions 1 includes a protruded portion 11 (such as a protruded step-like portion) provided on the corresponding side of the space 91 and may further include a coupling hole 13 formed in the protruded portion 11, wherein the coupling hole 13 can be a threaded hole.

The second coupling portions 3 are provided on two opposite sides of the adaptor 7 and correspond to the first coupling portions 1. In this embodiment, each of the second coupling portions 3 can be a projecting piece extending from the corresponding side of the adaptor 7, wherein the projecting piece is selectively provided on one end of the side of the adaptor 7 and may be L-shaped. Each of the second coupling portions 3 further includes a mounting hole 31 for being coupled to a corresponding one of the coupling components 5 such that the corresponding coupling component 5 can be secured in position by means of the mounting hole 31.

The coupling components 5 are provided for coupling the first coupling portions 1 to the second coupling portions 3. The coupling components 5 can be, but not limited to, screws, for example, headed screws.

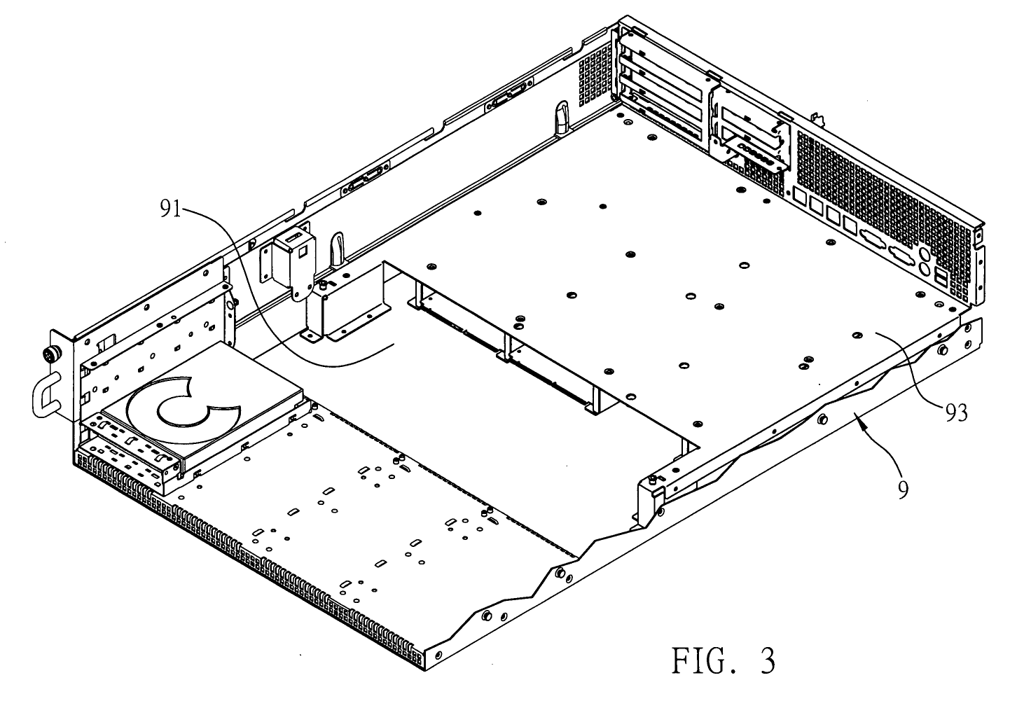

FIGS. 3 to 6 are schematic diagrams showing an adaptor being mounted to a server having a space by the fixing structure according to the preferred embodiment of the present invention.

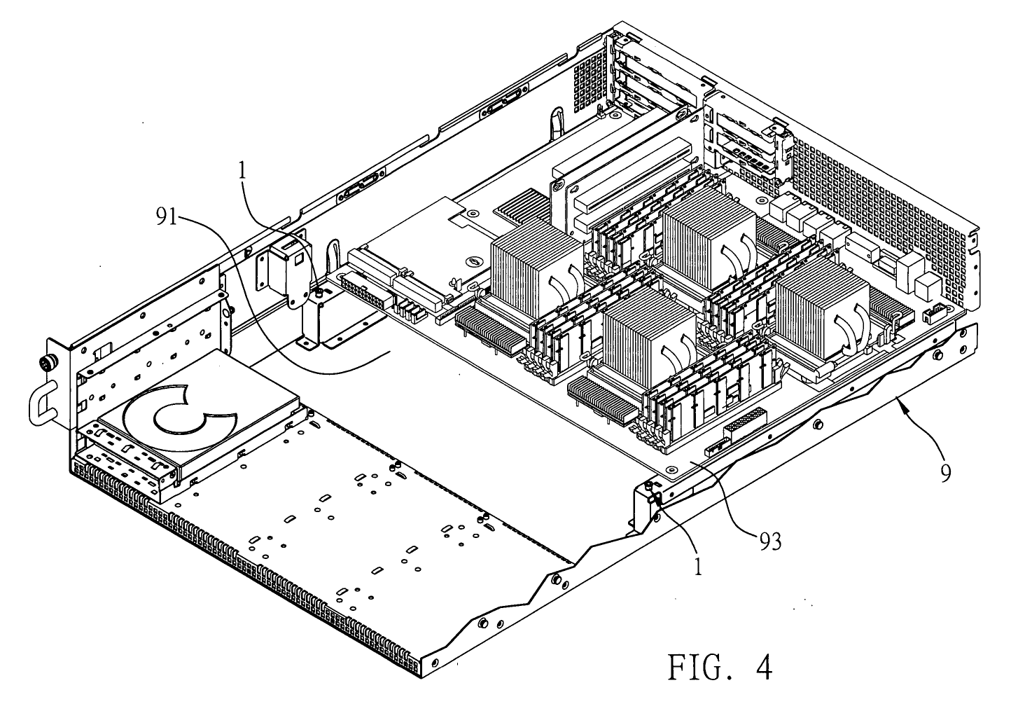

As shown in FIG. 3, for the server 9 provided with a large motherboard 93, the space 91 is reserved. This allows the adaptor 7 to be mounted or demounted easily to the server 9 without moving the motherboard 93 in the present invention, unlike the prior art that the power supplies must be electrically connected to the adaptor before the motherboard is mounted to the server. As shown in FIG. 4, the server 9 can be divided into an upper layer and a lower layer, wherein the upper layer is for accommodating the motherboard 93 on which a plurality of required system components are mounted, and the lower layer comprises the space 91 with the first coupling portions 1 being disposed on two opposite sides thereof.

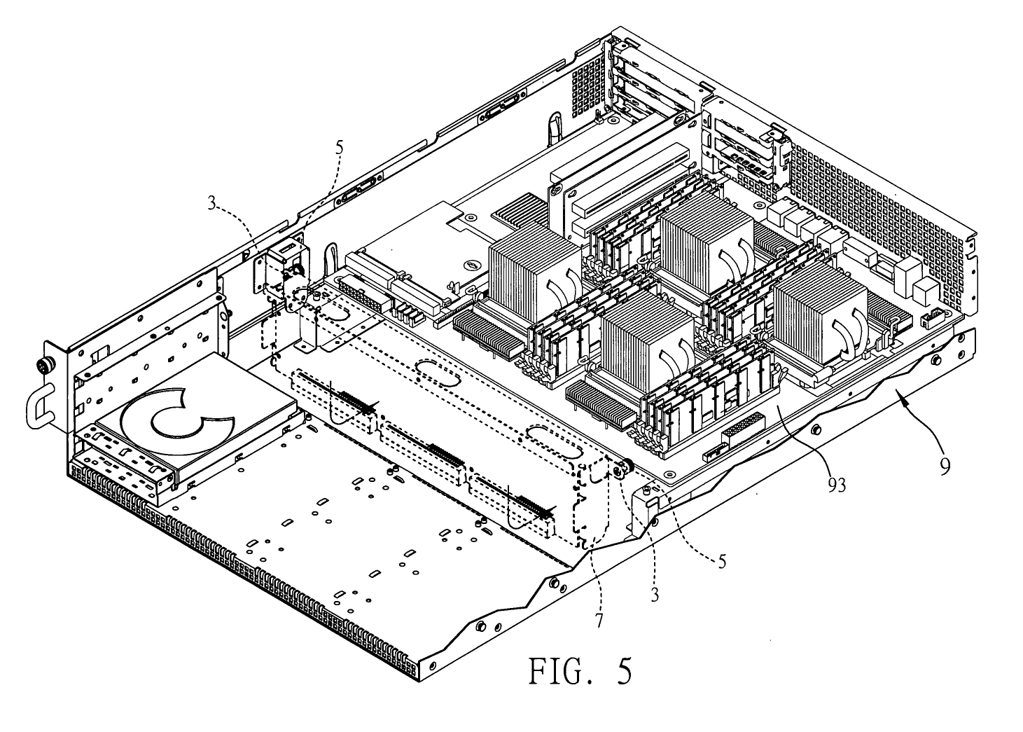

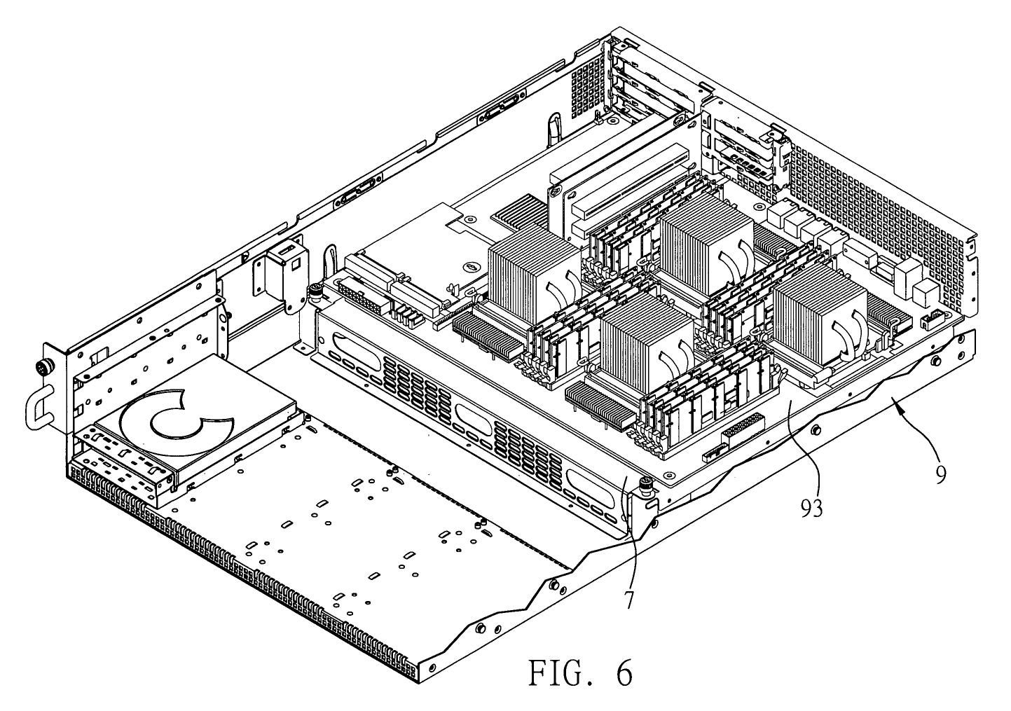

Referring to FIG. 5, the adaptor 7 can be mounted into the server 9. In this embodiment, the adaptor 7 with the second coupling portions 3 being provided on two opposite sides thereof and the coupling components 5 coupled to the second coupling portions 3 can be mounted in the space 91, wherein the second coupling portions 3 are coupled to the first coupling portions 1 by means of the coupling components 5. Accordingly, the adaptor 7 can be fixed in the server 9 as shown in FIG. 6.

To demount the adaptor 7 from the server 9, it only needs to release the bonding between the first coupling portions 1 and the second coupling portions 3. For example, in this embodiment, mounting or demounting of the adaptor 7 to or from the server 9 can easily be accomplished by screwing or unscrewing the coupling components 5 such as screws with fingers.

It should be noted, mounting of the adaptor to the server is illustrated by means of screwing in this embodiment, however other equivalent designs that are well known in the art such as clipping, pinning and the like for bonding the first coupling portions 1 to the second coupling portions 3 can also be used in the present invention.

Therefore, a large-size motherboard (e.g. a 3 U motherboard) can be used in this embodiment. Although such motherboard may occupy a large area, it does not impede assembly or disassembly of an adaptor to or from a server through the use of the fixing structure of the present invention as the adaptor 7 with the fixing structure of the present invention is able to slide into the space 91 at a proper gradient (as shown in FIG. 5). In other words, the side of the adaptor 7 with the electrical connection portions 71 (as shown in FIG. 1) can be inserted into the space 91 and under the motherboard 93. Moreover, as shown in FIG. 6, since the height of the adaptor 7 is smaller than the height of the space 91 under the motherboard 93, the gradient of the adaptor 7 gradually becomes smaller along with the adaptor 7 sliding underneath the motherboard 93, such that the motherboard 93 is not affected by the movement of the adaptor 7. Furthermore, when disassembling the adaptor 7 from the server 9, the adaptor 7 can be pulled upwards to make the inclination between the adaptor 7 and the bottom of the server larger, such that the adaptor 7 would not touch the motherboard 93.

Compared to the prior art, there is no need to screw or unscrew a plurality of screws during the mounting or demounting process of the adaptor with respect to the server by use of the fixing structure according to the present invention. Therefore, the present invention can solve the complexity problem in mounting or demounting of the adaptor in the prior art and also makes assembly or disassembly of power supplies convenient to implement. Moreover, in the case of using a largest motherboard, the fixing structure of the present invention allows the adaptor to be easily mounted or demounted to or from the server without affecting the motherboard.

As a result, it is convenient in mounting or demounting the adaptor for connecting power supplies to the server without moving the motherboard through the use of the fixing structure of the present invention, such that the drawbacks of the prior art can be overcome by the present invention.

The foregoing descriptions of the detailed embodiments are only illustrated to disclose the features and functions of the present invention and not restrictive of the scope of the present invention. For example, although a large motherboard such as a 3 U motherboard is illustrated in this embodiment, 1 U or 2 U motherboard or any other large-size motherboard can also be used in the present invention. Thus, it should be understood to those in the art that all modifications and variations according to the spirit and principle in the disclosure of the present invention should fall within the scope of the appended claims.

What is claimed is:

1. A structure for fixing an adaptor to a server having a space, the structure comprising:
at least one first coupling portion provided on at least one side of the space;
at least one second coupling portion provided on at least one side of the adaptor and corresponding to the at least one first coupling portion; and
at least one coupling component provided on the at least one second coupling portion, for securely coupling the at least one first coupling portion to the at least one second coupling portion.

2. The structure of claim 1, wherein the first coupling portion includes a protruded portion disposed on the side of the space.

3. The structure of claim 2, wherein the first coupling portion further includes a coupling hole formed in the protruded portion.

4. The structure of claim 3, wherein the coupling hole is a threaded hole.

5. The structure of claim 1, wherein the second coupling portion includes a projecting piece extending from the side of the adaptor.

6. The structure of claim 5, wherein the projecting piece is disposed on one end of the side of the adaptor.

7. The structure of claim 1, wherein the second coupling portion further includes a mounting hole for being coupled to the coupling component.

8. The structure of claim 1, wherein the coupling component is a screw.

9. The structure of claim 8, wherein the screw is a headed screw.
